(19) United States
(12) Patent Application Publication
(10) Pub. No.: US 2005/0056939 A1
(43) Pub. Date: Mar. 17, 2005

(54) Thin-film capacitor and method of producing the capacitor

(75) Inventors: Kiyoshi Ooi, Nagano-shi (JP); Tomoo Yamasaki, Nagano-shi (JP); Akio Rokugawa, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/939,340

(22) Filed: Sep. 14, 2004

(30) Foreign Application Priority Data
Sep. 16, 2003 (JP) 2003-323146

(51) Int. Cl. H01L 21/44

(52) U.S. Cl. 257/761

(57) ABSTRACT

A thin-film capacitor comprising a first thin-film electrode, a second thin-film electrode, and a thin dielectric film arranged therebetween and formed of a tantalum oxide layer and an aluminum oxide layer neighboring thereto. A method of producing such a thin-film capacitor is also disclosed.

### BACKGROUND OF THE INVENTION

1. Field of the Invention

The present invention relates to a thin-film capacitor, to be incorporated in a circuit board used for semiconductor packages and the like, and to a method of producing the capacitor.

2. Description of the Related Art

When capacitor parts are necessary in a semiconductor package, it has been known to incorporate them in the circuit board of the semiconductor package (see, for example, Japanese Unexamined Patent Publications (Kokai) NOs. 2001-110675 and 2002-260960, corresponding to U.S. Pat. No. 6,498,714 B1 and U.S. 2002/0122283 A1, respectively.). The capacitor incorporated in the circuit board has a thin film stacked structure in which a dielectric thin film is arranged between thin conductor films forming two electrodes. It is also called thin-film capacitor.

As a conductor for forming electrodes of the thin-film capacitor, there can be used titanium, platinum, copper, aluminum or the like. A capacitor using copper electrodes is known as a low-resistance capacitor. As a dielectric, Ta₂O₅, which is a material having a high dielectric constant, is usually used. A capacitor constituted by copper (Cu) electrodes and the Ta₂O₅ dielectric is fabricated by anodically treating (anodizing) a Ta film formed on a Cu film that serves as one electrode to thereby form a Ta₂O₅ dielectric film, and forming a Cu film thereon to serve as another electrode.

Another thin film may also be provided between the thin conductor film and the thin dielectric film in order to improve capacitor characteristics or to improve adhesion between the thin films. For example, it has been known to provide a thin Ti film as a barrier metal layer between the Cu film and the Ta film to prevent the interruption of anodic treatment that results from the leakage of a treating current as Cu dissolves in the treating solution (electrolyte) at the time of anodically treating the Ta film on the Cu film. It has further been known to arrange, for example, a thin Cr film between the Ta₂O₅ film and the Cu film to improve the adhesion between them. Further, it has been known to insert thin alumina (Al₂O₃) films between the two Cu electrodes and the Ta₂O₅ film for improving the quality of the Ta₂O₅ film in the capacitor of the Cu/Ta₂O₅/Cu stacked structure for LSIs for wireless communication equipment (T. Ishikawa, et al, High-Capacitance Cu/Ta₂O₅/Cu MIM Structure for SoC Applications Featuring a Single-Mask Add-on Process, 2002 International Electron Devices Meetings, IEEE (2002)), though this is not for the circuit boards.

### SUMMARY OF THE INVENTION

As described above, in the thin-film capacitor, a Ta₂O₅ film is usually used as a dielectric material. However, a capacitor using the Ta₂O₅ film has a disadvantage of a small withstand voltage (about 5 V) and it permits a large leakage current to flow.

In conducting the anodic treatment, further, it is difficult to precisely convert the whole Ta film into the Ta₂O₅ film. Usually, therefore, the anodic treatment is finished while leaving part of the Ta film. In this case, as Ta is a material having a high electric resistance, Ta that is remaining raises the electric resistance of the capacitor.

In a case where Cu is used as the electrode, when a Ti film is inserted between the Cu film and the Ta film to prevent the elution of Cu at the time of anodically treating Ta, Ti, which is also a material having a high electric resistance, increases the electrode resistance, making it difficult to utilize properties of Cu which is a low-resistance material to a sufficient degree.

It is therefore an object of the present invention to provide a thin-film capacitor which has a small leakage current and makes it easy to lower the resistance of the electrodes, as a result of solving the above-mentioned problems.

A thin-film capacitor of the present invention comprises a first thin-film electrode, a second thin-film electrode, and a thin dielectric film arranged therebetween and formed of a tantalum oxide layer and an aluminum oxide layer neighboring thereto.

The thin-film capacitor of the invention can be produced by a method of producing a thin-film capacitor by forming a first thin electrode layer, successively forming an aluminum layer and a tantalum layer or a tantalum nitride layer thereon, anodically treating the tantalum layer or the tantalum nitride layer and the aluminum layer to form a thin dielectric film comprising a tantalum oxide layer and an aluminum oxide layer, and forming a second thin electrode layer on the tantalum oxide layer.

In the thin-film capacitor of this invention, the dielectric portion between the electrodes forms the structure of a series connection of the tantalum oxide film and the aluminum oxide film, and can decrease a potential difference applied across the tantalum oxide portion, which has a high dielectric constant but has poor withstand voltage, while it can improve the withstand voltage of the capacitor owing to the presence of the aluminum oxide portion having an excellent withstand voltage. The aluminum oxide film is effective in preventing the diffusion of highly migrating metals such as Cu. According to the present invention, therefore, even when Cu is used for the electrode material, there can be realized a capacitor having a low resistance without the need of providing a barrier metal layer formed by Ti having a high resistance. In conducting the anodic treatment, all the tantalum is oxidized, and no high resistance tantalum remains, which contributes to lowering the resistance.

### BRIEF DESCRIPTION OF THE DRAWINGS

FIG. 1 schematically illustrates a thin-film capacitor according to the present invention;

FIGS. 2A and 2B illustrate potential differences applied to the dielectric portions in a conventional capacitor and in the capacitor of the invention, respectively;

FIG. 3 illustrates a circuit board incorporating a thin-film capacitor of the present invention;

FIG. 4 illustrates another circuit board incorporating a thin-film capacitor according of the present invention;

FIG. 5 illustrates another embodiment of the thin-film capacitor of the present invention;

FIGS. 6A to 6D illustrate the production of the capacitor of Example 1;

FIG. 7 illustrates the capacitor produced in Example 2; and

FIGS. 8A and 8B are graphs showing leakage current characteristics of a capacitor of the comparative example and the capacitor of Example 1, respectively.

### DETAILED DESCRIPTION OF THE INVENTION

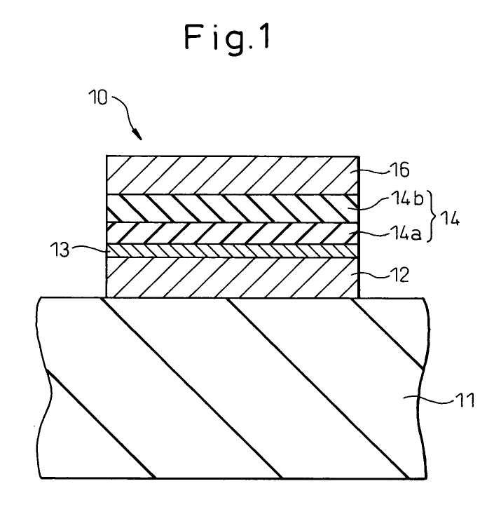

A thin-film capacitor 10 of the present invention is schematically illustrated in FIG. 1. The thin-film capacitor 10 is constituted by a first thin electrode film 12, a dielectric film 14 located thereon and formed of an aluminum oxide layer 14a and a tantalum oxide layer 14b, and a second thin electrode film 16 located thereon.

The two thin electrode films 12 and 16 are formed by using a conductor material. Representative conductor materials include platinum (Pt), gold (Au), ruthenium (Ru), copper (Cu) and nickel (Ni). Use of Cu which is a low-resistance material makes it possible to obtain a capacitor having a small resistance. The two thin electrode films 12 and 16 may be made of the same material or different materials.

The thin dielectric film 14 is formed of an aluminum oxide (hereinafter often expressed as Al₂O₃) layer 14a and a tantalum oxide (hereinafter often expressed as Ta₂O₅) layer 14b. The Ta₂O₅ layer 14b has a high dielectric constant, making it possible to obtain a capacitor of a large capacity, but its withstand voltage is not favorable. The Al₂O₃ layer 14a compensates for the lack of withstand voltage of the Ta₂O₅ layer 14b but has an inferior dielectric constant. In the capacitor of the invention, it is preferred that the thicknesses of the two layers are determined by taking the properties of the two layers into consideration so as to realize the characteristics required for a certain capacitor. Usually, it is preferred that the thickness of the Al₂O₃ layer 14a is decreased to as small as possible so that the total dielectric constant of the capacitor does not decrease unnecessarily. For instance, the Ta₂O₅ layer 14b may have a thickness of about 0.1 to about 0.5μ, and the Al₂O₃ layer 14a may have a thickness of about 0.01 to about 0.1 μm.

The oxide layers 14a and 14b can be formed by anodically treating the aluminum (Al) layer and the tantalum (Ta) layer, that have been successively formed on the first thin electrode film 12, together. The Ta₂O₅ layer can also be obtained by anodically treating a tantalum nitride (TaN) layer that is formed instead of the Ta layer. The thickness of the metal layer oxidized by the treatment can be controlled by the applied voltage. The layers to be subjected to the anodic treatment are very thin. In oxidizing the Al layer following the oxidation of the Ta layer, therefore, it is difficult to so control that only the Al layer is entirely oxidized without affecting the underlying thin electrode layer 12. Usually, therefore, the applied voltage is so controlled that the oxidation ends before the oxidation reaches the interface between the Al layer and the thin electrode film 12. As a result, there remains a thin Al film 13 as shown in FIG. 1 between the Al₂O₃ layer 14a and the first thin electrode film 12. Nevertheless, a capacitor of a structure with no remaining Al film 13 as a result of completely oxidizing the Al layer, is included in the scope of the invention as a matter of course.

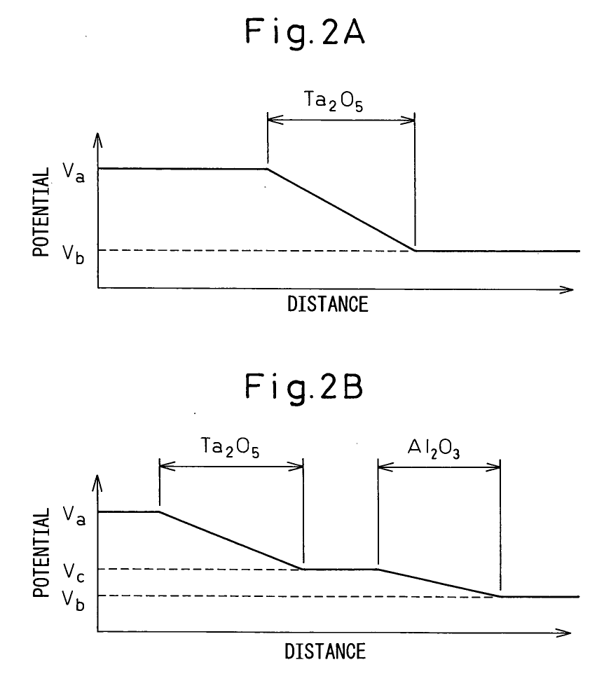

In a conventional thin-film capacitor in which a dielectric portion between the electrodes is constituted by a Ta₂O₅ film, a potential difference Va−Vb which is a difference between a potential Va on one electrode and a potential Vb on the other electrode is applied to the dielectric portion as illustrated in FIG. 2A when the capacitor operates. In the thin-film capacitor of the invention illustrated in FIG. 1, on the other hand, the dielectric portion between the electrodes 12 and 16 has a structure in which the Al₂O₃ film 14a and the Ta₂O₃ film 14b are connected in series. Therefore, when the same potential difference Va−Vb as that of the prior art of FIG. 2A is applied across the two electrodes, the potential difference Va−Vc applied to the tantalum oxide portion having a high dielectric constant but an inferior withstand voltage can be decreased to be smaller than Va−Vb as illustrated in FIG. 2B. Accordingly, the leakage current can be decreased.

The thin-film capacitor 10 of the invention can also include thin films or layers other than those described, as required. For example, when the thin electrode film is formed by using Cu, a thin Cr film (not shown) may be included between the Ta₂O₅ layer 14b and the thin electrode layer 16 of Cu to improve adhesion between them.

The capacitor 10 of the invention is incorporated in the circuit board used in a semiconductor package or the like, and is positioned on any insulating support member 11 which is a member of the circuit board. A representative example of the circuit board incorporating the capacitor of the invention is a printed wiring board. A build-up board formed by alternately stacking the wiring layers and the insulating layers on one surface or on both surfaces of the printed wiring board which is a core substrate is also included in the circuit board that is referred to here. The capacitor of the invention may be used as one incorporated in the rerouted wiring layer of chip-size packages, or for any other application.

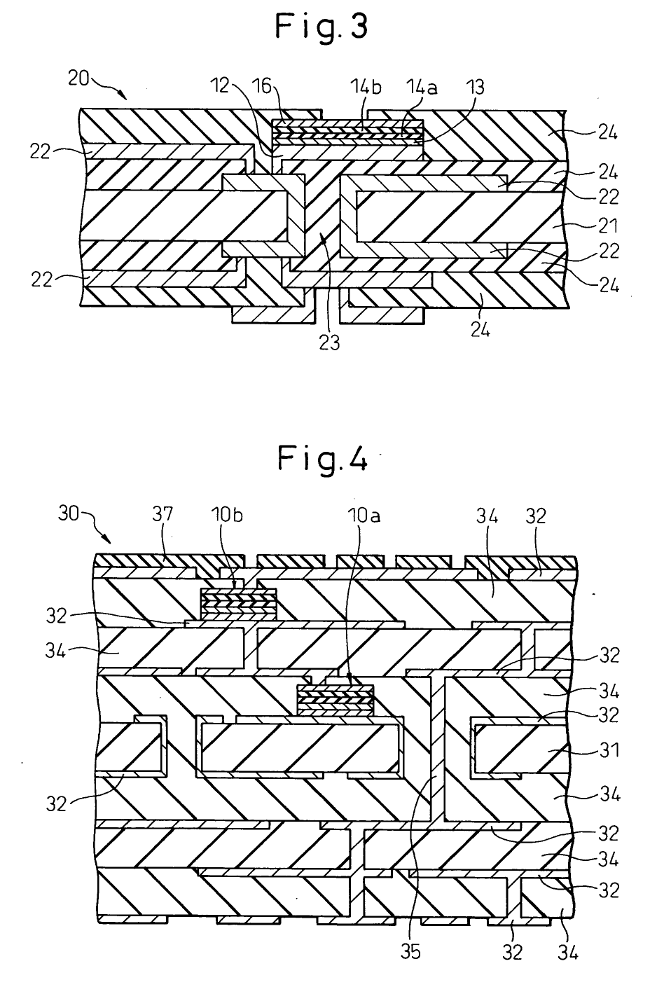

FIG. 3 illustrates an example of incorporating the capacitor of the invention in the uppermost layer of a build-up wiring board 20. The build-up wiring board 20 is formed by alternately stacking the wiring layers 22 and the insulating layers 24 on the upper and lower surfaces of the printed board 21 which is a core substrate having a through hole 23 formed in a predetermined portion. The upper and lower wiring layers 22 of the printed board 21 are communicated together through a wiring conductor deposited on the inner wall of the through hole 23. The thin-film capacitor of the invention (stacked structure of lower electrode 12, remaining Al layer 13, Al₂O₃ layer 14a, Ta₂O₅ layer 14b and upper electrode 16) is incorporated above the through hole 23. The lower electrode 12 of the capacitor is connected to the lower wiring layer 22, and the upper electrode 16 is connected to a semiconductor chip or the like by forming, for example, a bump (not shown), in the opening provided in the uppermost insulating layer 24 covering the upper electrode 16.

FIG. 4 illustrates an example of incorporating the capacitor of the invention within a build-up board 30. This build-up board 30 is also formed by alternately stacking wiring layers 32 and an insulating layers 34 on the upper and lower surfaces of a printed board 31 which is a core substrate. The upper and lower wiring layers 32 of the printed board 31 are connected together through a wiring conductor filled in a through hole 35 formed in the insulating material that penetrates the printed board 31. A thin-film capacitor 10a of the invention is formed on the wiring layer 32 directly provided on the printed board 31 and, in addition, a thin-film capacitor 10b of the invention is formed on the upper wiring layer 32. The upper thin-film capacitor 10b is connected to the uppermost wiring layer 32 through an opening formed in the insulating layer 34 covering the upper thin-film capacitor 10b, the uppermost wiring layer being protected by a protection film 37.

The build-up boards, such as those illustrated in FIGS. 3 and 4, incorporating the capacitor or capacitors and methods of their production are well known (see, for example, Japanese Unexamined Patent Publications (Kokai) NOs. 2001-110675 and 2002-260960), and are not described here in detail.

The thin-film capacitor 10 (FIG. 1) of the present invention can be easily produced by forming the stacked structure constituting the capacitor on any support member 11 by known methods of depositing and patterning a material. For example, the deposition of the materials for the respective films can be carried out by any process, such as sputtering, evaporation, plating or chemical vapor deposition (CVD). The dielectric film of the capacitor can be easily obtained by anodically treating Ta and Al of the stack together. The anodic treatment itself is widely known.

In the boards incorporating the capacitor or capacitors of the invention illustrated in FIGS. 3 and 4, the upper electrode and the lower electrode of the capacitor are connected to members which overlay and underlie the capacitor. Although the two electrodes 12 and 16, and the Al film 13, Al₂O₃ layer 14a and Ta₂O₅ layer 14b interposed therebetween, have the same size, they need not necessarily have the same size.

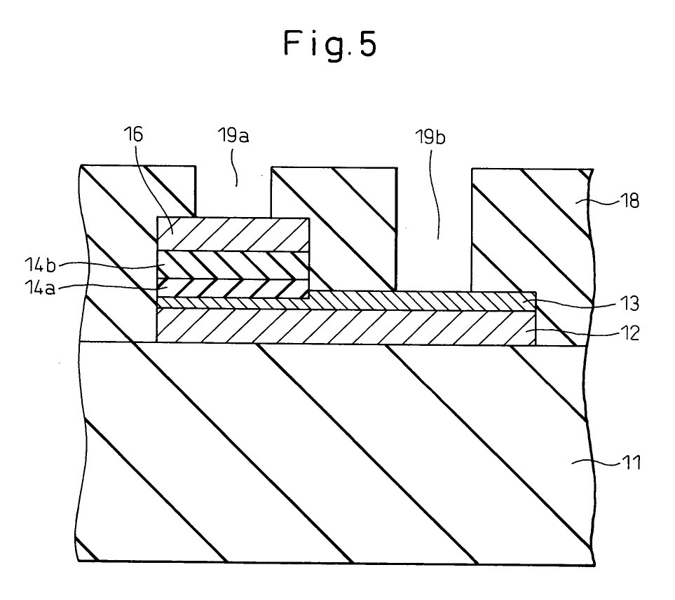

For instance, both the upper electrode and the lower electrode may be connected to members located at one side of the capacitor. In this case, the two electrodes have different sizes and shapes. FIG. 5 illustrates a capacitor in which both electrodes are connected to the upper wiring lines. In the capacitor of FIG. 5, the lower electrode 12 and the Al film 13 are formed in sizes larger than the Al₂O₃ layer 14a, Ta₂O₅ layer 14b and upper electrode 16, which are located thereon, and are extending toward the right side. An insulating layer 18 is formed to cover the capacitor, and the upper electrode 16 and the lower electrode 12 are connected to the upper wiring lines (not shown) through an opening 19a formed in the insulating film 18 and reaching the upper electrode 16 and through an opening 19b reaching the lower electrode 12, respectively. The Al film 13 may not be formed on the portion of the lower electrode 12 extending toward the right, so that the lower electrode 12 can be connected to the upper wiring line without through the Al film 13.

Although the above-mentioned thin-film capacitor of the invention has the Al₂O₃ film 14a formed only between the Ta₂O₅ film 14b of a high dielectric constant and the one electrode 12, another Al₂O₃ film may be formed between the Ta₂O₅ film 14b and another electrode 16.

### EXAMPLES

The invention will now be described making reference to examples which, however, are not intended to limit the invention.

### Example 1

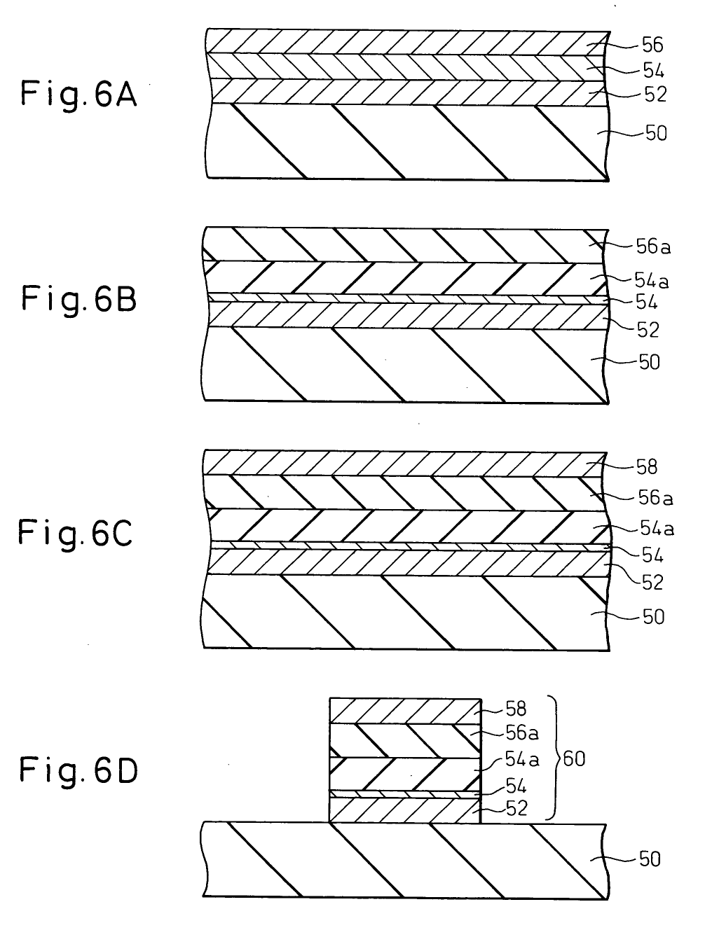

On a support member 50 of an insulating material (epoxy resin) shown in FIG. 6A, there were successively formed a Cu film 52 (10 μm thick), an Al film 54 (1 μm thick) and a Ta film 56 (0.15 μm thick) by sputtering. Next, the support member 50 having the above films formed was immersed in an aqueous solution of citric acid and was subjected to the anodic treatment by the application of a DC voltage of 200 V to convert the Ta film 56 into a Ta₂O₅ film 56a (FIG. 6B) and to convert part of the Al film 54 into an Al₂O₃ film 54a (FIG. 6B). Subsequently, as shown in FIG. 6C, a Cu film 58 (10 μm thick) was formed by sputtering on the Ta₂O₅ film 56a. Then, the films were successively patterned by dry etching to produce a thin-film capacitor 60 illustrated in FIG. 6D.

### Example 2

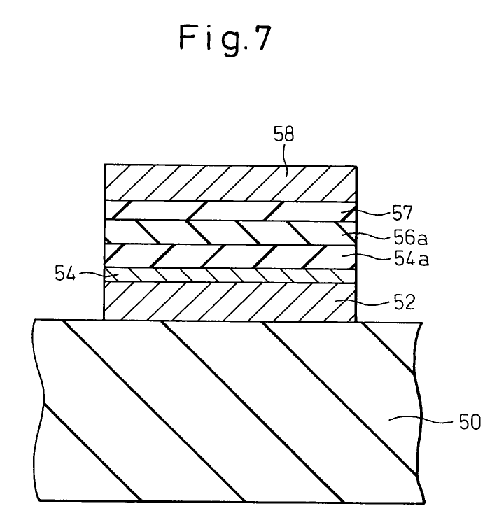

Example 1 was repeated with the exception of further forming an Al film (0.1 μm thick) on the Ta film 56 of FIG. 6A, and anodically treating three films, i.e., the Al film, and the underlying Ta film and Al film together (at an applied voltage of 250 V), to produce a capacitor having a dielectric film of a three-layer structure of Al₂O₃ film 54a/Ta₂O₅ film 56a/Al₂O₃ film 57 illustrated in FIG. 7. Of the two Al films, the one on the Ta film was completely oxidized, and no Al film existed between the Al₂O₃ film 57 and the upper electrode 58.

### Comparative Example

The same thin-film capacitor as that of Example 1 was prepared but it had a Ti film of 1 μm thick instead of the Al₂O₃ film and the Al film between the lower electrode and the Ta₂O₅ film.

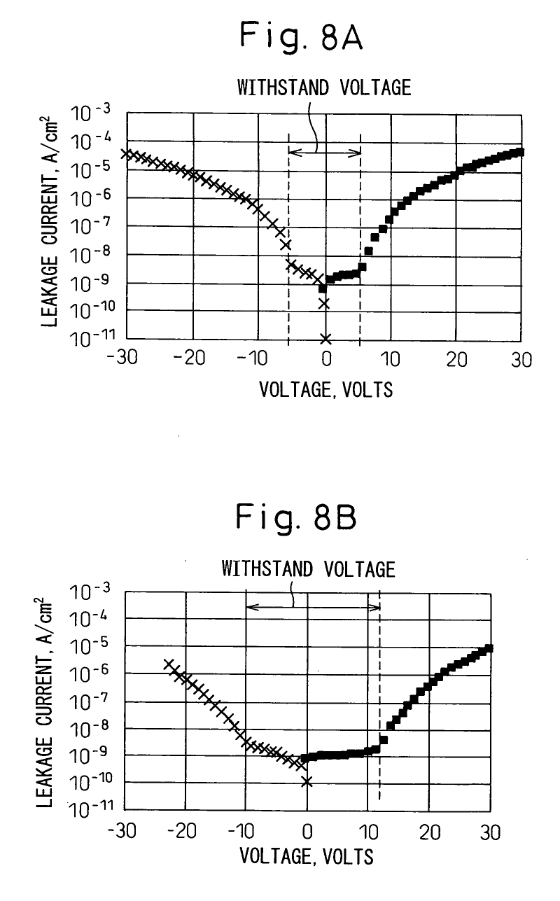

The capacitor obtained in Comparative Example and the capacitor obtained in Example 1 were measured for their leakage current characteristics (I−V measurement) to obtain the results as shown in FIGS. 8A and 8B, respectively. The capacitor of Comparative Example has a practicable withstand voltage in a range of about ±5 V (FIG. 8A), whereas the capacitor of the present invention has a practicable withstand voltage over a range of from about −10 to about 12 V (FIG. 8B) owing to only the provision of the Al₂O₃ layer between the one electrode and the Ta₂O₅ dielectric layer. In this range, the amount of leakage current of the capacitor of the invention is about 10⁻⁹ A/cm², exhibiting favorable leakage current characteristics as compared to the amount of leakage current of 10⁻⁸ A/cm² of the capacitor for LSIs used in the wireless communication equipment, as taught in T. Ishikawa et al. referred to above.

1. A thin-film capacitor comprising a first thin-film electrode, a second thin-film electrode, and a thin dielectric film arranged therebetween and formed of a tantalum oxide layer and an aluminum oxide layer neighboring thereto.

2. A thin-film capacitor according to claim 1 wherein said aluminum oxide layer is included only between said tantalum oxide layer and one of said thin electrode films.

3. A thin-film capacitor according to claim 1 wherein said aluminum oxide layer is contacted to one of said thin electrode films through an aluminum film.

4. A thin-film capacitor according to claim 1 wherein said aluminum oxide layer is formed by anodically treating an aluminum layer on one of said thin electrode layers.

5. A thin-film capacitor according to claim 1 wherein said thin-film capacitor is incorporated in a circuit board.

6. A thin-film capacitor according to claim 1 wherein said first and second thin electrode films are made of copper.

7. A method of producing a thin-film capacitor comprising a first thin-film electrode, a second thin-film electrode, and a thin dielectric film arranged therebetween and formed of a tantalum oxide layer and an aluminum oxide layer neighboring thereto, the method comprising forming a first thin electrode layer, successively forming an aluminum layer and a tantalum layer or a tantalum nitride layer thereon, anodically treating the tantalum layer or the tantalum nitride layer and the aluminum layer to form a thin dielectric film comprising a tantalum oxide layer and an aluminum oxide layer, and forming a second thin electrode layer on the tantalum oxide layer.
